(19) United States
(12) Patent Application Publication
(10) Pub. No.: US 2020/0300508 A1
(43) Pub. Date: Sep. 24, 2020

(54) COATED SOLAR REFLECTOR PANEL

(71) Applicant: Trevor Powell, Highvale, Queensland (AU)

(72) Inventor: Trevor Powell, Highvale, Queensland (AU)

(21) Appl. No.: 16/649,210

(22) PCT Filed: Sep. 21, 2018
(86) PCT No.: PCT/AU2018/051037

§ 371 Date: Mar. 20, 2020

(30) Foreign Application Priority Data
Sep. 22, 2017 (AU) 2017903869

(51) Int. Cl. F24S 23/77; C09D 5/33; F24S 23/70; G02B 1/10; G02B 19/00; H01L 31/054

(52) U.S. Cl. CPC F24S 23/77; C09D 5/004; F24S 23/82; G02B 1/10; F24S 2080/015; H01L 31/054; F24S 2023/86; F24S 2023/872; G02B 19/0019

(57) ABSTRACT

The present invention is in the field of solar energy collectors. In particular, the invention is directed to solar energy collectors that operate by concentrating solar radiation onto an absorber using a reflector. The invention may be embodied in the form of a unitary planar solar radiation reflector array having a plurality of upwardly facing reflective surfaces each of which is configured to reflect incident solar radiation, wherein each upwardly facing reflective surface is formed by coating a substrate with a coating material. The coating material may be a metallic coating of substantially even thickness formed by a metal deposition method such as a vapour deposition method or a thermal spray method.

### FIELD OF THE INVENTION

The present invention is in the field of solar energy collectors. In particular, the invention is directed to solar energy collectors that operate by concentrating solar radiation onto an absorber using a reflector.

### BACKGROUND

It is known in the art of renewable energy to harness power from the sun by concentrating solar radiation onto an absorber using a reflector, such as a polished metal mirror. The reflector is generally configured to concentrate solar radiation such that it is incident on, and heats, an absorber. A heat transfer medium (such as an oil) is typically pumped through the absorber where it absorbs heat energy. The absorbed heat energy is typically released at a location remote to the collector where the energy is converted into useful work. A common method for energy conversion involves pumping the heated medium to a boiler, where a heat exchanger transfers heat energy from the medium to water. Steam is collected from the boiler and directed to a rotary turbine and generator to produce electricity. Alternatively, the heated medium may be used to directly heat a building, or as input heat energy in an industrial process.

Parabolic trough collectors are a type of solar thermal collector which typically incorporate an elongate reflector having (in cross-section) a parabolic profile. The energy of the solar radiation incides on the reflector parallel to its plane of symmetry and is therefore focused along a focal line. A tube containing a heat transfer medium runs the length of the trough at its focal line, the reflector oriented such that reflected solar radiation concentrates on the tube to heat the heat transfer medium. To maintain efficiency, the trough is normally rotatable about its long axis, such that the trough is able to track the sun for the majority of the day.

While clearly useful, parabolic reflectors are difficult and expensive to fabricate. Existing parabolic trough collectors generally utilise curved mirror glass which is difficult and expensive to manufacture.

Furthermore, the support structures maintaining the reflector clear of the ground are complex, heavy and difficult to transport to remote sites.

For substantial installations, support structures typically involve the use of heavy duty columns, which in turn prescribe the need for massive foundations and associated footings. Because of the weight and sheer size of a trough assembly (and the attendant high wind forces bearing on it), the support structures must be massive and therefore expensive. Installing the foundations may require deep excavation, this adding yet further expense and complexity to installation.

The supporting structures must be able to not only support the weight of the reflector trough, but also withstand the significant forces inevitably occasioned on the collector by wind. Apart from dislodging the trough from the ground, wind can also lead to flexing of the reflective surfaces thereby disrupting the focal line of the trough. Accordingly, a complex framing structure fabricated from heavy duty metal tubing is often used to support the reflective surfaces of a parabolic trough collector. The framing structure maintains the mirror reflective surface the correct distance from the absorber, and also oriented at the required angle so as to form a rigid reflective parabolic trough assembly that can be directed toward the sun.

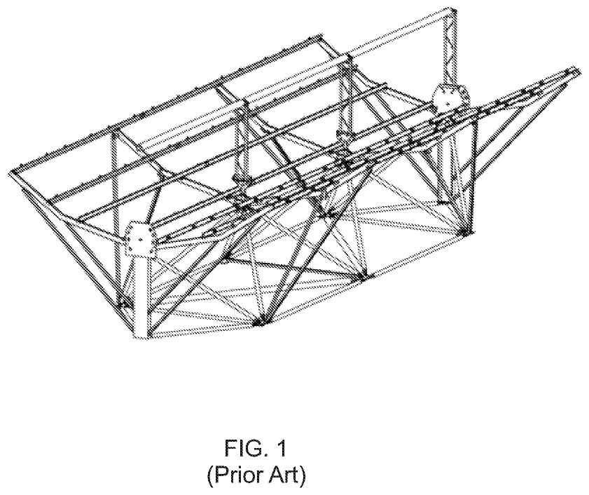

An example of the complex framing typically used to support the reflective surfaces of a trough is shown at FIG. 1. Given the size, it will be appreciated that such an arrangement cannot be built in a factory environment and then transported as a whole to the installation site. Instead, the frame must be built on site by an exacting and painstaking process of assembling the individual frame members as required, and then fastening together. Such complexity may preclude implementation in under-developed countries where engineering capabilities and equipment (such as cranes) are often lacking.

For trough-based solar collectors used in the production of electricity, increased installation costs negatively impact the Levelized Cost of Electricity (LCOE), that being a universal measure of the economic viability of a solar power plant. Ultimately, solar thermal power generation can only be of benefit to mankind where underpinned by sound economics.

Various simplified solar energy collector systems are known in the art which are lightweight and therefore require less robust supporting hardware. However, further improvement is still required with regard to weight, ease of manufacture and cost.

It is an aspect of the present invention to overcome or ameliorate a problem of the prior art by providing a simple, light weight and low cost reflector array of the type used in solar thermal energy collection. It is a further aspect to provide a useful alternative to prior art reflector arrays.

The discussion of documents, acts, materials, devices, articles and the like is included in this specification solely for the purpose of providing a context for the present invention. It is not suggested or represented that any or all of these matters formed part of the prior art base or were common general knowledge in the field relevant to the present invention as it existed before the priority date of each claim of this application.

### SUMMARY OF THE INVENTION

After considering this description it will be apparent to one skilled in the art how the invention is implemented in various alternative embodiments and alternative applications. However, although various embodiments of the present invention will be described herein, it is understood that these embodiments are presented by way of example only, and not limitation. As such, this description of various alternative embodiments should not be construed to limit the scope or breadth of the present invention. Furthermore, statements of advantages or other aspects apply to specific exemplary embodiments, and not necessarily to all embodiments covered by the claims.

Throughout the description and the claims of this specification the word “comprise” and variations of the word, such as “comprising” and “comprises” is not intended to exclude other additives, components, integers or steps.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may.

It will be understood that while certain advantages of the invention are described herein it is not represented that all embodiments of the invention will possess all advantages. Some embodiments of the invention may provide no advantage whatsoever and may represent no more than an alternative to the prior art.

The present invention is predicated at least in part on the proposal that an effective, yet highly economical reflector may be fabricated from a coated substrate. Accordingly, in a first aspect, the present invention provides a unitary planar solar radiation reflector array having a plurality of upwardly facing reflective surfaces each of which is configured to reflect incident solar radiation, wherein each upwardly facing reflective surface is formed by coating a substrate with a coating material. In use, the coating of the upwardly facing reflective surface acts to direct solar radiation onto an absorber disposed over the reflective surfaces, so as to heat the absorber.

As used herein, the term “upwardly facing reflective surface” means a surface, which when the reflector array is installed and in use, faces upwardly and generally toward the sun. Of course, during manufacture and transport the upwardly facing reflective surface may face in any direction whatsoever.

In many embodiments, the coating is applied to an upwardly facing reflective surface of substrate, i.e. a surface of the substrate that when the reflector array is installed and in use, faces upwardly and generally toward the sun. As an example of such an embodiment, a reflective coating may be deposited directly onto a surface of the substrate that, when the reflector array is installed and in use, faces upwardly and generally toward the sun.

In other embodiments the coating may be applied to a downwardly facing surface of substrate, i.e. a surface of the substrate that when the reflector array is installed and in use, faces downwardly and generally away from the sun. As an example of such an embodiment, the substrate may be an optically transparent UV stable plastic and a reflective coating is applied to the underside of the plastic. Thus, when the upper side of the transparent plastic is directed generally toward the sun the reflective coating which has been applied to the opposing (lower) side acts to receive incoming solar radiation through the transparent plastic, and reflect that radiation (again, through the transparent plastic) toward an overlying absorber.

The reflector array of the present invention may be a unitary plastic panel having a plurality of upwardly facing planar reflective surfaces, each reflective surface inclined at an angle to the plane of the panel, the angle of each reflective surface being configured to reflect solar radiation onto an absorber disposed over the surfaces.

Alternatively, the reflector array may comprise a unitary plastic panel having a plurality of upwardly facing curvilinear reflective surfaces. Each of the curvilinear reflective surfaces may be of such small dimension and shallow curvature that it may be approximated to a planar surface for the purpose of angling the reflector to the plane of the panel. The reflective surfaces will be varying distances from the absorber, with the curvature of those more proximal being configured to provide a shorter focal length compared with those more distal which will have a longer focal length.

The present invention is a significant departure from prior art reflectors which typically involve a number of glass mirrors, or in some instances a continuous parabolic reflector. To the best of the Applicant's knowledge, the prior art has not disclosed the application of a reflective coating to a unitary substrate so as to provide a unitary planar reflector assembly having a plurality of upwardly facing reflective surfaces as described herein. It is important to note that the present reflector array may be distinguished from some existing reflector arrays on the basis at least that the array is unitary and the use of a coating material on a substrate such that the coating material forms an upwardly facing reflective surface.

As will be understood, the material used to coat the substrate forming the upwardly facing reflective surface may be selected by reference to any parameter deemed relevant by the skilled person. Reflectance of the deposited material is a primary parameter given the general aim of optimising the amount of solar radiation incident on an absorber. In that regard, metallic materials are generally preferred. Accordingly, in one embodiment of the first aspect, the deposited coating comprises a metal or a compound comprising a metal.

The metallic coating may be provided by use of a paint (such as Rust-Oleum™ mirror finish spray paint) comprising a suspension of metallic particles which, upon evaporation of the solvent base, form a substantially smooth metallic surface that has reflective properties. While useful to an extent, painted coatings have imperfections and unevenness and accordingly are applicable where low-efficiency reflection is sufficient.

In one embodiment of the first aspect, the coating material forms a film. The film may be formed in situ on the upwardly facing reflective surfaces by spraying a liquid onto a surface, or by otherwise depositing a liquid or a vapour thereon.

Alternatively, the film may be a pre-formed reflective film or foil, and applied to a surface of the substrate so as to provide an upwardly facing reflective surface. For example, metalized mylar film has a highly reflective, mirror-like surface. It is an oriented polyester film with a thin coating of aluminium that has been vacuum deposited on to the surface of the film. An adhesive may be applied to the back of the film, and then applied to surface(s) of the substrate so as to form a reflective coating. Alternatively, the film or foil may be fused to a surface or vacuum-formed about the reflector array.

Another parameter useful in the selection of a coating material or a coating method is the smoothness or the evenness of the coating. As will be appreciated, any scattering of light by the coating is to be generally avoided so far as possible, or so far as practicable for an application. Accordingly, coatings that are formed from materials that are devoid of macroscopic granules or inconsistencies are preferred. Moreover, the material or coating method should be selected such than when the material is in place on the surface, present a substantially flat face upwardly. In one embodiment of the first aspect, the deposited coating has a substantially even thickness.

Given that the upwardly facing reflective surface typically has a high level of evenness or smoothness (and in some embodiments, may be entirely flat) it is preferred than any film be a thin film. Use of a thin film decreases the opportunity for any unevenness in the film to develop, and as such the surface of the film is more likely to be strictly parallel to the underlying surface. Accordingly, in one embodiment of the first aspect, the coating material forms a thin film.

In one embodiment of the first aspect, the coating has a thickness of less than about 100 μm. In another embodiment of the first aspect, wherein the coating has a thickness of less than about 20 μm. In some embodiments, the coating has a thickness of less than about 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm or 1 μm.

In one embodiment of the first aspect, the coating material is deposited on the substrate by a metal deposition method. In such methods, a metal in a non-continuous form (such as in a spray, vapour or particulate form) is brought into proximity to the substrate, and the metal deposited on the surface of the substrate to form a reflective surface that, in use, will face upwardly toward the sun. The coating may be incrementally built up on the surface until the required thickness is achieved. Such methods are often used to deposit a thin metallic film on the surface of a polymer. Metals and metal compounds useful in this context include aluminium, chromium, nickel, silver, cadmium, tin, zinc, tungsten and copper.

Some metal deposition methods are reliant on a surface treatment to energize the surface of the surface so that the metal coating will effectively adhere. The methods may add energy and material onto the surface only, ensuring the bulk of the reflector array remains relatively cool and unaltered. Thus, surface properties are positively modified with minimal or no change to the underlying material.

Other metal deposition methods are reliant on a plasma (i.e. clouds of electrons and ions from which particles can be extracted). A plasma may be used to reduce process temperatures by adding kinetic energy to the upwardly facing reflective surface rather than thermal energy.

Some metal deposition methods are reliant on a vacuum being formed about the surface to be coated. Some methods require the use of a vacuum chamber to ensure cleanliness and control of the process.

In one embodiment of the first aspect, the coating is deposited on the surface by a vapour deposition method. This method is reliant on the coating material being presented to the surface to be coated in a vapour state via condensation, chemical reaction, or conversion. Examples of vapour deposition methods include physical vapour deposition (PVD) and chemical vapour deposition (CVD). In PVD, the surface to be coated is subjected to plasma bombardment. In CVD, thermal energy heats gases in a coating chamber, driving the deposition reaction. Vapour deposition methods are usually performed within a vacuum chamber.

In one embodiment of the first aspect, the vapour deposition method is a physical vapour deposition method, including an ion plating method, a plasma-based method, an ion implantation method, a sputtering method, a sputter deposition method, a laser surface alloying method and a laser cladding method.

Physical vapour deposition methods are typically reliant on dry vacuum deposition in which a coating material is deposited over the surface to be coated. Reactive PVD hard coating methods generally require a method for depositing the metal, an active gas (such as nitrogen, oxygen, or methane), and plasma bombardment of the substrate.

PVD methods include ion plating, ion implantation, sputtering, and laser surface alloying.

Plasma-based plating is one form of ion plating, whereby the surface to be coated is positioned proximal to a plasma. Ions and neutrons from the plasma are accelerated by a negative bias onto the surface to be coated with a range of energies.

This technique produces coatings that typically range from 0.008 mm to 0.025 mm, although conditions can be altered to achieve thicker and thinner coatings. Ion plating can provide excellent surface covering ability, good adhesion, flexibility in tailoring film properties (e.g., morphology, density, and residual film stress), and in-situ cleaning of the substrate prior to film deposition. Ion plating methods are capable of depositing a wide variety of metals including alloys of titanium, aluminium, copper, gold, and palladium.

Ion implantation methods do not produce a discrete coating on the substrate surface, but alter the elemental chemical composition of the surface by forming an alloy with energetic ions. In this embodiment, the coating consists of the alloy. In ion implantation techniques, a beam of charged ions of an element of the coating is formed by streaming a gas into the ion source. In the ion source, electrons emitted from a hot filament, ionize the gas to form a plasma. An electrically biased electrode focuses the ions into a beam. Where there is sufficient energy, ions alloy with the substrate thereby altering the surface composition. Three ion implantation methods may be selected from: beam implementation, direct ion implantation, and plasma source implementation.

Ion implantation may be used for any element that can be vaporized and ionized in a vacuum chamber.

In some embodiments, the upwardly facing reflective surfaces of the reflector array may be coated using sputtering or sputter deposition methods. Sputtering alters the physical properties of a surface. In this process, a gas plasma discharge is provided between a cathode coating material and an anode substrate. Positively charged gas ions are accelerated into the cathode. The impact displaces atoms from the cathode, which then impact the anode and coat the substrate. A film forms on the upwardly facing reflective surface as atoms adhere to the substrate. The deposits are typically thin, ranging from 0.00005 mm to 0.01 mm. This method is often used to coat with silver, aluminium, chromium, titanium, copper, molybdenum, tungsten, and gold. Three techniques for sputtering are available to the skilled person for potential use in the present invention: diode plasmas, RF diodes, and magnetron-enhanced sputtering.

Sputter deposition is capable of depositing coatings of metals, alloys, compounds, and dielectrics on surfaces. Compared to other deposition processes, sputter deposition is relatively inexpensive, and may be preferred in some applications for reasons of economy only.

In other embodiments of the invention, the upwardly facing reflective surfaces may be formed by way of laser surface modification. These methods are similar to surface melting, but alloying is promoted by injecting another material into the melt pool. In this embodiment, the coating consists of the alloyed region of the substrate.

Laser cladding is one type of laser surface alloying which may be used to selectively coat a defined area. Typically, a thin layer of metal (which may be a powder metal) is bonded with a base metal via the application of heat and pressure. A metal powder may be fed into a carbon dioxide laser beam above the upwardly facing reflective surface, melted in the beam, and then deposited on the surface. Powder feeding may be performed using a carrier gas in a manner analogous to thermal spray systems. Large areas may be coated by moving the substrate under the beam and overlapping deposition tracks. Grinding and polishing are often required as finishing steps.

Laser cladding may generally be used to apply the same or similar materials to those operable with thermal spraying methods. Deposition rates may be altered by modulating any one or more of laser power, feed rates, and traverse speed. Coating thicknesses can range from several hundred microns to several millimetres, although process conditions may be varied to provide for thickness outside of this range.

In one embodiment of the first aspect, the vapour deposition method is a chemical vapour deposition method, including a sputtering method, an ion plating method, a plasma-enhanced method, a low-pressure method, a laser-enhanced method, an active reactive evaporation, an ion beam method, and a laser evaporation method. The various methods are distinguished by the manner in which the precursor gases are converted into reactive gas mixtures.

The steps in a typical CVD process are as follows: generation of the reactive gas mixture, transport of reactant gas to the surface to be coated, adsorption of the reactants on the surface to be coated, and reaction of the adsorbents to form the coating.

To explain further, the reactant gas mixture is contacted with the substrate of the reflector array. The coating material is delivered by a precursor material (termed a reactive vapour) which may be dispensed as a gas, liquid, or in solid phase. The gases are fed into a chamber under ambient pressures and temperatures while solids and liquids are provided at high temperature and/or low pressure. Once resident in the chamber, energy is applied to the substrate surface to facilitate the coating reaction with the carrier gas.

Pre-treatment of the substrate surface is generally required in vapour deposition methods, and particularly in CVD. Mechanical and/or chemical means may be used before the substrate enters the deposition reactor. Cleaning is typically effected by ultrasonic cleaning and/or vapour degreasing. To facilitate adhesion of the coating, vapour honing may be used. During the coating process, surface cleanliness is maintained to prevent particulates from entering in the coating. Mild acids or bases may be used to slough oxide layers which may have formed during the heat-up step. Post-treatment of the coating may include exposure to heat to cause diffusion of the coating material across the surface.

CVD methods may be used to provide coatings of aluminium, nickel, tungsten, chromium, or titanium carbide.

In one embodiment of the first aspect, the coating material is deposited on the substrate surface by a thermal spray method, including a combustion torch method, a flame spraying method, a high velocity oxy fuel method, a detonation gun method, an electric arc spraying method and a plasma spraying method. One step that may be involved in a thermal coating process is substrate preparation: This step typically involves removal of any oily residues, and often minor surface roughening. Surface roughening is required to ensure proper bonding of the coating material to the substrate surface. Roughening may be achieved by the use of grit blasting with alumina.

Where required, masking may be applied to areas of the reflector array that are not to be coated. As further discussed infra, some embodiments comprise non-reflective surfaces. Non-reflective surfaces may be generated in one pass in the CVD process without masking, by dimpling or roughening surfaces intended to be non-reflective before the deposition step.

Once any masking is applied, the coating is deposited. The coating material may be sprayed from rod or wire stock or from powder material. An operator feeds material to a flame so as to melt it. The molten stock is then stripped from the end of the wire and atomized by a high-velocity stream of compressed air (or other gas), thereby coating the material onto the substrate surface. Depending on the surface, bonding may occur due to mechanical engagement with the roughened surface and/or because of electrostatic forces.

Parameters that affect the deposition of metals in thermal spray applications include the particle's temperature, velocity, angle of impact, and the extent of any reaction with gases during the deposition process.

Where necessary, there may be some finishing or polishing step required so as to remove any overspray and confer a required reflectance or reflectivity on the coating.

There currently exists three basic categories of thermal spray technologies: combustion torch methods (including flamespray, high-velocity oxy fuel, and detonation gun methods), electric (wire) arc methods, and plasma arc methods.

Flame spraying methods involve feeding gas and oxygen through a combustion flame spray torch. The coating material (in powder or wire form) is fed into the flame. The coating material is heated to about or higher than its melting point, and then accelerated by combustion of the coating material. The so-formed molten droplets flow on the surface to form a continuous and even coating.

High-velocity oxy fuel (HVOF) methods require the coating material to be heated to a temperature of about or greater than its melting point, and then deposited on the upwardly facing reflective surface by a high-velocity combustion gas stream. The method is typically carried out in a combustion chamber to enable higher gas velocities. Fuels used in this method include hydrogen, propane, or propylene.

Advantageously in the present application, coatings applied with HVOF exhibit little or no porosity. Deposition rates are relatively high, and the coatings have acceptable bond strength. Coating thicknesses from 0.000013 mm to 3 mm are available.

Combustion torch and detonation gun methods combine oxygen and acetylene with pulsed powder containing carbides, metal binders, and oxides. The mix is introduced into a water-cooled barrel, and detonated to generate expanding gas that heats and accelerates the powder materials while converting same into a plastic-like state (typically at temperatures of 1,100 degrees Celsius to 19,000 degrees Celsius). A coating may be built up by way of repeated, controlled detonations. Typical coating thicknesses range from 0.05 mm to 0.5 mm, although thinner and thicker coatings can be achieved.

In electric arc spraying, an electric arc is formed between the termini of two wires composed of the coating material. The arc continuously melts the wire while a gas jet blows the molten droplets toward the surface. Coating material may be applied thinly or thickly as required, however can result in coatings having an undesirable porosity or low bond strength.

Plasma spraying relies on introduction of a flow of gas (typically argon) between a water-cooled anode and a cathode. A direct current arc passes through the gas stream causing ionization and the formation of a plasma. The plasma heats the coating material (in powder form) to a molten state. Compressed gas directs the material onto the surface to be coated.

Preferably, the coating is made from a material and/or deposited on the upwardly facing reflective surface such that no polishing of the coating is required to confer a required reflectance.

Irrespective of what material is used to form the coating, or what method is used to deposit the coating, the coating has at least a certain reflectance or reflectivity. Where reflectance is considered, it is preferred that the surface of the coating provides predominantly specular reflection over diffuse reflection. For specular surfaces, reflectance will be nearly zero at all angles except at the appropriate reflected angle; that is, reflected radiation will follow a different path from incident radiation for all cases other than radiation normal to the surface. In some embodiments, the surface of the coating has a proportional specular reflection (as distinct from diffuse reflection) of at least about 50%, 60%, 70%, 80%, 90%, 95%, 96%, 97%, 98%, 99%, or 99.9%.

Where reflectivity is considered, the coating has a % reflectivity at a visible wavelength (such as 400 nm, 450 nm, 500 nm, 550 nm, 600 nm, 650 nm, or 700 nm) or infrared wavelength (such as 1 μm, 10 μm, 100 μm, or 1000 μm), or ultraviolent wavelength (such as 1 nm, 10 nm, or 100 nm) of at least about 50%, 60%, 70%, 80%, 90%, 95%, 96%, 97%, 98%, 99%, or 99.9%.

Overall, PVD methods are preferred, and particularly metallizing methods carried out in a vacuum chamber at low temperatures. These methods are able to provide thin, and very even films which are highly reflective and durable. Highly reflective coatings may be produced by sputtering aluminium or thermal evaporation followed by a protective topcoat. Coating techniques such as sputtering, cathodic arc, and thermal evaporation may be used to produce coatings having a required minimum reflectivity. For example, magnetron sputtering may be performed by high rate, planar or rotary cathodes. Thermal evaporation may be accomplished by precise, filament type evaporation sources. In some embodiments, coating may be accomplished by PECVD (Plasma Enhanced Chemical Vapour Deposition) processes, using DC or MF (40 MHz) plasma sources. Reflectivity of at least 90% may be provided with aluminium, and at least 95% with silver. For reasons of economy, aluminium may be preferred in some circumstances.

Where polishing or finishing of a metal coating is required to confer or improve reflectance or specular reflection, this may be achieved by way of re-melting the metal. Automated laser radiation methods are known in the unrelated arts of tooling and medical engineering, and are contemplated to be useful in the manufacture of the present reflector arrays. In laser radiation techniques, a thin surface layer is melted with surface tension leading to material flow from the peaks to the valleys of the surface under treatment. Material is not removed, but is instead relocated while molten. The laser beam is guided over the surface in contour-aligned patterns. A surface roughness of Ra ˜0.05 μm is achievable with laser polishing, depending on the material and the initial roughness. This surface quality may be sufficient for at least some applications of the present invention.

In one embodiment of the first aspect, the unitary planar solar radiation reflector array has an axis and/or a plane. Some, most or all of the upwardly facing reflective surfaces may be disposed generally along a line or on a plane of the reflector array. In the preferred embodiment discussed infra, elongate upwardly facing reflective surfaces act as reflectors, and all are disposed in a planar manner.

In one embodiment of the first aspect, the upwardly facing reflective surfaces of the reflector array are each disposed at an angle to the axis or the plane. In one embodiment of the first aspect, the angle of the upwardly facing reflective surface is fixed.

In one embodiment of the first aspect, at least two upwardly facing reflective surfaces of the reflector array are each disposed at different angles. Typically, the angle of each upwardly facing reflective surface increases incrementally across the reflector array, such that each upwardly facing reflective surface reflects incident solar radiation onto an absorber disposed over the array. Thus, an upwardly facing reflective surface that is disposed almost below the absorber will have a relatively shallow angle, while a surface that is displaced some distance lateral to the absorber (for example toward the edge of the array) will have a relatively steep angle.

Generally, the absorber will be disposed along a central axis of the reflector array with upwardly facing reflective surfaces disposed on either side of the absorber. Thus, upwardly facing reflective surfaces that are proximal to the central axis of the reflector array have a relatively shallow angle, while surfaces distal to the central axis have a relatively steep angle.

In one embodiment of the first aspect, the array is formed as a panel. The panel may have an upwardly facing side which comprises the upwardly facing reflective surfaces (which act as reflectors), and a downwardly facing side. The downwardly facing side of the unitary planar reflector array may contact and preferably be secured to a mount configured to elevate the panel and also allow pivoting of the array so as to allow the upwardly facing reflective surfaces to be directed toward the sun.

In the form of a panel, the unitary planar reflector array may have a low profile. A low profile is preferred because of the lesser amount of material used to form the substrate. Where the substrate of the reflector array is moulded or extruded in substantially solid form, material (such as plastic) interior to the substrate is preferably minimised for reasons of reducing cost and weight. A low profile may be gained by configuring the upwardly facing reflective surfaces to be narrow and/or for the surfaces to be disposed at shallow angles.

In one embodiment the profile of the reflector array is less than about 5 mm, 6 mm, 7 mm, 8 mm, 9 mm, 10 mm, 11 mm, 12 mm, 13 mm, 14 mm, 15 mm, 16 mm, 17 mm, 18 mm, 19 mm, 20 mm, 21 mm, 22 mm, 23 mm, 24 mm, 25 mm, 26 mm, 27 mm, 28 mm, 29 mm, 30 mm, 31 mm, 32 mm, 33 mm, 34 mm, 35 mm, 36 mm, 37 mm, 38 mm, 39 mm, 40 mm, 41 mm, 42 mm, 43 mm, 44 mm, 45 mm, 46 mm, 47 mm, 48 mm, 49 mm, 50 mm, 51 mm, 52 mm, 53 mm, 54 mm, 55 mm, 56 mm, 57 mm, 58 mm, 59 mm, 60 mm, 61 mm, 62 mm, 63 mm, 64 mm, 65 mm, 66 mm, 67 mm, 68 mm, 69 mm, 70 mm, 71 mm, 72 mm, 73 mm, 74 mm, 75 mm, 76 mm, 77 mm, 78 mm, 79 mm, 80 mm, 81 mm, 82 mm, 83 mm, 84 mm, 85 mm, 86 mm, 87 mm, 88 mm, 89 mm, 90 mm, 91 mm, 92 mm, 93 mm, 94 mm, 95 mm, 96 mm, 97 mm, 98 mm, 99 mm, or 100 mm. Each increment provides advantage given the proportional incremental decrease in the amount of material used for fabricating the unitary planar reflector array.

In one embodiment of the first aspect, the unitary planar solar radiation reflector array has a cross-sectional thickness of less than about 100 mm.

In one embodiment of the first aspect, the unitary planar solar radiation reflector array has a cross-sectional thickness of less than about 10 mm.

In one embodiment of the first aspect, the upwardly facing reflective surfaces of the reflector array are elongate and extend in parallel rows, as is shown in the preferred embodiments drawn herein.

Use of shallow angles minimizes the volume of material below the upwardly facing reflective surfaces. Preferably, the maximum angle for an upwardly facing reflective surface, or the average angle of all upwardly facing reflective surfaces is about 45 degrees, 44 degrees, 43 degrees, 42 degrees, 41 degrees, 40 degrees, 39 degrees, 38 degrees, 37 degrees, 36 degrees, 35 degrees, 34 degrees, 33 degrees, 32 degrees, 31 degrees, 30 degrees, 29 degrees, 28 degrees, 27 degrees, 26 degrees, 25 degrees, 24 degrees, 23 degrees, 22 degrees, 21 degrees, 20 degrees, 19 degrees, 18 degrees, 17 degrees, 16 degrees, 15 degrees, 14 degrees, 13 degrees, 12 degrees, 11 degrees, 10 degrees, 9 degrees, 8 degrees, 7 degrees, 6 degrees, 5 degrees, 4 degrees, 3 degrees, 2 degrees or 1 degree. Each increment provides advantage given the proportional incremental decrease in the amount of material used for fabricating the unitary planar reflector array.

Use of narrow elongate and narrow upwardly facing reflective surfaces minimises the volume of material below the upwardly facing reflective surfaces. Preferably, the maximum width for an upwardly facing reflective surface, or the maximum width of all upwardly facing reflective surfaces is about 1000 mm, 999 mm, 998 mm, 997 mm, 996 mm, 995 mm, 994 mm, 993 mm, 992 mm, 991 mm, 990 mm, 989 mm, 988 mm, 987 mm, 986 mm, 985 mm, 984 mm, 983 mm, 982 mm, 981 mm, 980 mm, 979 mm, 978 mm, 977 mm, 976 mm, 975 mm, 974 mm, 973 mm, 972 mm, 971 mm, 970 mm, 969 mm, 968 mm, 967 mm, 966 mm, 965 mm, 964 mm, 963 mm, 962 mm, 961 mm, 960 mm, 959 mm, 958 mm, 957 mm, 956 mm, 955 mm, 954 mm, 953 mm, 952 mm, 951 mm, 950 mm, 949 mm, 948 mm, 947 mm, 946 mm, 945 mm, 944 mm, 943 mm, 942 mm, 941 mm, 940 mm, 939 mm, 938 mm, 937 mm, 936 mm, 935 mm, 934 mm, 933 mm, 932 mm, 931 mm, 930 mm, 929 mm, 928 mm, 927 mm, 926 mm, 925 mm, 924 mm, 923 mm, 922 mm, 921 mm, 920 mm, 919 mm, 918 mm, 917 mm, 916 mm, 915 mm, 914 mm, 913 mm, 912 mm, 911 mm, 910 mm, 909 mm, 908 mm, 907 mm, 906 mm, 905 mm, 904 mm, 903 mm, 902 mm, 901 mm, 900 mm, 899 mm, 898 mm, 897 mm, 896 mm, 895 mm, 894 mm, 893 mm, 892 mm, 891 mm, 890 mm, 889 mm, 888 mm, 887 mm, 886 mm, 885 mm, 884 mm, 883 mm, 882 mm, 881 mm, 880 mm, 879 mm, 878 mm, 877 mm, 876 mm, 875 mm, 874 mm, 873 mm, 872 mm, 871 mm, 870 mm, 869 mm, 868 mm, 867 mm, 866 mm, 865 mm, 864 mm, 863 mm, 862 mm, 861 mm, 860 mm, 859 mm, 858 mm, 857 mm, 856 mm, 855 mm, 854 mm, 853 mm, 852 mm, 851 mm, 850 mm, 849 mm, 848 mm, 847 mm, 846 mm, 845 mm, 844 mm, 843 mm, 842 mm, 841 mm, 840 mm, 839 mm, 838 mm, 837 mm, 836 mm, 835 mm, 834 mm, 833 mm, 832 mm, 831 mm, 830 mm, 829 mm, 828 mm, 827 mm, 826 mm, 825 mm, 824 mm, 823 mm, 822 mm, 821 mm, 820 mm, 819 mm, 818 mm, 817 mm, 816 mm, 815 mm, 814 mm, 813 mm, 812 mm, 811 mm, 810 mm, 809 mm, 808 mm, 807 mm, 806 mm, 805 mm, 804 mm, 803 mm, 802 mm, 801 mm, 800 mm, 799 mm, 798 mm, 797 mm, 796 mm, 795 mm, 794 mm, 793 mm, 792 mm, 791 mm, 790 mm, 789 mm, 788 mm, 787 mm, 786 mm, 785 mm, 784 mm, 783 mm, 782 mm, 781 mm, 780 mm, 779 mm, 778 mm, 777 mm, 776 mm, 775 mm, 774 mm, 773 mm, 772 mm, 771 mm, 770 mm, 769 mm, 768 mm, 767 mm, 766 mm, 765 mm, 764 mm, 763 mm, 762 mm, 761 mm, 760 mm, 759 mm, 758 mm, 757 mm, 756 mm, 755 mm, 754 mm, 753 mm, 752 mm, 751 mm, 750 mm, 749 mm, 748 mm, 747 mm, 746 mm, 745 mm, 744 mm, 743 mm, 742 mm, 741 mm, 740 mm, 739 mm, 738 mm, 737 mm, 736 mm, 735 mm, 734 mm, 733 mm, 732 mm, 731 mm, 730 mm, 729 mm, 728 mm, 727 mm, 726 mm, 725 mm, 724 mm, 723 mm, 722 mm, 721 mm, 720 mm, 719 mm, 718 mm, 717 mm, 716 mm, 715 mm, 714 mm, 713 mm, 712 mm, 711 mm, 710 mm, 709 mm, 708 mm, 707 mm, 706 mm, 705 mm, 704 mm, 703 mm, 702 mm, 701 mm, 700 mm, 699 mm, 698 mm, 697 mm, 696 mm, 695 mm, 694 mm, 693 mm, 692 mm, 691 mm, 690 mm, 689 mm, 688 mm, 687 mm, 686 mm, 685 mm, 684 mm, 683 mm, 682 mm, 681 mm, 680 mm, 679 mm, 678 mm, 677 mm, 676 mm, 675 mm, 674 mm, 673 mm, 672 mm, 671 mm, 670 mm, 669 mm, 668 mm, 667 mm, 666 mm, 665 mm, 664 mm, 663 mm, 662 mm, 661 mm, 660 mm, 659 mm, 658 mm, 657 mm, 656 mm, 655 mm, 654 mm, 653 mm, 652 mm, 651 mm, 650 mm, 649 mm, 648 mm, 647 mm, 646 mm, 645 mm, 644 mm, 643 mm, 642 mm, 641 mm, 640 mm, 639 mm, 638 mm, 637 mm, 636 mm, 635 mm, 634 mm, 633 mm, 632 mm, 631 mm, 630 mm, 629 mm, 628 mm, 627 mm, 626 mm, 625 mm, 624 mm, 623 mm, 622 mm, 621 mm, 620 mm, 619 mm, 618 mm, 617 mm, 616 mm, 615 mm, 614 mm, 613 mm, 612 mm, 611 mm, 610 mm, 609 mm, 608 mm, 607 mm, 606 mm, 605 mm, 604 mm, 603 mm, 602 mm, 601 mm, 600 mm, 599 mm, 598 mm, 597 mm, 596 mm, 595 mm, 594 mm, 593 mm, 592 mm, 591 mm, 590 mm, 589 mm, 588 mm, 587 mm, 586 mm, 585 mm, 584 mm, 583 mm, 582 mm, 581 mm, 580 mm, 579 mm, 578 mm, 577 mm, 576 mm, 575 mm, 574 mm, 573 mm, 572 mm, 571 mm, 570 mm, 569 mm, 568 mm, 567 mm, 566 mm, 565 mm, 564 mm, 563 mm, 562 mm, 561 mm, 560 mm, 559 mm, 558 mm, 557 mm, 556 mm, 555 mm, 554 mm, 553 mm, 552 mm, 551 mm, 550 mm, 549 mm, 548 mm, 547 mm, 546 mm, 545 mm, 544 mm, 543 mm, 542 mm, 541 mm, 540 mm, 539 mm, 538 mm, 537 mm, 536 mm, 535 mm, 534 mm, 533 mm, 532 mm, 531 mm, 530 mm, 529 mm, 528 mm, 527 mm, 526 mm, 525 mm, 524 mm, 523 mm, 522 mm, 521 mm, 520 mm, 519 mm, 518 mm, 517 mm, 516 mm, 515 mm, 514 mm, 513 mm, 512 mm, 511 mm, 510 mm, 509 mm, 508 mm, 507 mm, 506 mm, 505 mm, 504 mm, 503 mm, 502 mm, 501 mm, 500 mm, 499 mm, 498 mm, 497 mm, 496 mm, 495 mm, 494 mm, 493 mm, 492 mm, 491 mm, 490 mm, 489 mm, 488 mm, 487 mm, 486 mm, 485 mm, 484 mm, 483 mm, 482 mm, 481 mm, 480 mm, 479 mm, 478 mm, 477 mm, 476 mm, 475 mm, 474 mm, 473 mm, 472 mm, 471 mm, 470 mm, 469 mm, 468 mm, 467 mm, 466 mm, 465 mm, 464 mm, 463 mm, 462 mm, 461 mm, 460 mm, 459 mm, 458 mm, 457 mm, 456 mm, 455 mm, 454 mm, 453 mm, 452 mm, 451 mm, 450 mm, 449 mm, 448 mm, 447 mm, 446 mm, 445 mm, 444 mm, 443 mm, 442 mm, 441 mm, 440 mm, 439 mm, 438 mm, 437 mm, 436 mm, 435 mm, 434 mm, 433 mm, 432 mm, 431 mm, 430 mm, 429 mm, 428 mm, 427 mm, 426 mm, 425 mm, 424 mm, 423 mm, 422 mm, 421 mm, 420 mm, 419 mm, 418 mm, 417 mm, 416 mm, 415 mm, 414 mm, 413 mm, 412 mm, 411 mm, 410 mm, 409 mm, 408 mm, 407 mm, 406 mm, 405 mm, 404 mm, 403 mm, 402 mm, 401 mm, 400 mm, 399 mm, 398 mm, 397 mm, 396 mm, 395 mm, 394 mm, 393 mm, 392 mm, 391 mm, 390 mm, 389 mm, 388 mm, 387 mm, 386 mm, 385 mm, 384 mm, 383 mm, 382 mm, 381 mm, 380 mm, 379 mm, 378 mm, 377 mm, 376 mm, 375 mm, 374 mm, 373 mm, 372 mm, 371 mm, 370 mm, 369 mm, 368 mm, 367 mm, 366 mm, 365 mm, 364 mm, 363 mm, 362 mm, 361 mm, 360 mm, 359 mm, 358 mm, 357 mm, 356 mm, 355 mm, 354 mm, 353 mm, 352 mm, 351 mm, 350 mm, 349 mm, 348 mm, 347 mm, 346 mm, 345 mm, 344 mm, 343 mm, 342 mm, 341 mm, 340 mm, 339 mm, 338 mm, 337 mm, 336 mm, 335 mm, 334 mm, 333 mm, 332 mm, 331 mm, 330 mm, 329 mm, 328 mm, 327 mm, 326 mm, 325 mm, 324 mm, 323 mm, 322 mm, 321 mm, 320 mm, 319 mm, 318 mm, 317 mm, 316 mm, 315 mm, 314 mm, 313 mm, 312 mm, 311 mm, 310 mm, 309 mm, 308 mm, 307 mm, 306 mm, 305 mm, 304 mm, 303 mm, 302 mm, 301 mm, 300 mm, 299 mm, 298 mm, 297 mm, 296 mm, 295 mm, 294 mm, 293 mm, 292 mm, 291 mm, 290 mm, 289 mm, 288 mm, 287 mm, 286 mm, 285 mm, 284 mm, 283 mm, 282 mm, 281 mm, 280 mm, 279 mm, 278 mm, 277 mm, 276 mm, 275 mm, 274 mm, 273 mm, 272 mm, 271 mm, 270 mm, 269 mm, 268 mm, 267 mm, 266 mm, 265 mm, 264 mm, 263 mm, 262 mm, 261 mm, 260 mm, 259 mm, 258 mm, 257 mm, 256 mm, 255 mm, 254 mm, 253 mm, 252 mm, 251 mm, 250 mm, 249 mm, 248 mm, 247 mm, 246 mm, 245 mm, 244 mm, 243 mm, 242 mm, 241 mm, 240 mm, 239 mm, 238 mm, 237 mm, 236 mm, 235 mm, 234 mm, 233 mm, 232 mm, 231 mm, 230 mm, 229 mm, 228 mm, 227 mm, 226 mm, 225 mm, 224 mm, 223 mm, 222 mm, 221 mm, 220 mm, 219 mm, 218 mm, 217 mm, 216 mm, 215 mm, 214 mm, 213 mm, 212 mm, 211 mm, 210 mm, 209 mm, 208 mm, 207 mm, 206 mm, 205 mm, 204 mm, 203 mm, 202 mm, 201 mm, 200 mm, 199 mm, 198 mm, 197 mm, 196 mm, 195 mm, 194 mm, 193 mm, 192 mm, 191 mm, 190 mm, 189 mm, 188 mm, 187 mm, 186 mm, 185 mm, 184 mm, 183 mm, 182 mm, 181 mm, 180 mm, 179 mm, 178 mm, 177 mm, 176 mm, 175 mm, 174 mm, 173 mm, 172 mm, 171 mm, 170 mm, 169 mm, 168 mm, 167 mm, 166 mm, 165 mm, 164 mm, 163 mm, 162 mm, 161 mm, 160 mm, 159 mm, 158 mm, 157 mm, 156 mm, 155 mm, 154 mm, 153 mm, 152 mm, 151 mm, 150 mm, 149 mm, 148 mm, 147 mm, 146 mm, 145 mm, 144 mm, 143 mm, 142 mm, 141 mm, 140 mm, 139 mm, 138 mm, 137 mm, 136 mm, 135 mm, 134 mm, 133 mm, 132 mm, 131 mm, 130 mm, 129 mm, 128 mm, 127 mm, 126 mm, 125 mm, 124 mm, 123 mm, 122 mm, 121 mm, 120 mm, 119 mm, 118 mm, 117 mm, 116 mm, 115 mm, 114 mm, 113 mm, 112 mm, 111 mm, 110 mm, 109 mm, 108 mm, 107 mm, 106 mm, 105 mm, 104 mm, 103 mm, 102 mm, 101 mm, 100 mm, 99 mm, 98 mm, 97 mm, 96 mm, 95 mm, 94 mm, 93 mm, 92 mm, 91 mm, 90 mm, 89 mm, 88 mm, 87 mm, 86 mm, 85 mm, 84 mm, 83 mm, 82 mm, 81 mm, 80 mm, 79 mm, 78 mm, 77 mm, 76 mm, 75 mm, 74 mm, 73 mm, 72 mm, 71 mm, 70 mm, 69 mm, 68 mm, 67 mm, 66 mm, 65 mm, 64 mm, 63 mm, 62 mm, 61 mm, 60 mm, 59 mm, 58 mm, 57 mm, 56 mm, 55 mm, 54 mm, 53 mm, 52 mm, 51 mm, 50 mm, 49 mm, 48 mm, 47 mm, 46 mm, 45 mm, 44 mm, 43 mm, 42 mm, 41 mm, 40 mm, 39 mm, 38 mm, 37 mm, 36 mm, 35 mm, 34 mm, 33 mm, 32 mm, 31 mm, 30 mm, 29 mm, 28 mm, 27 mm, 26 mm, 25 mm, 24 mm, 23 mm, 22 mm, 21 mm, 20 mm, 19 mm, 18 mm, 17 mm, 16 mm, 15 mm, 14 mm, 13 mm, 12 mm, 11 mm, 10 mm, 9 mm, 8 mm, 7 mm, 6 mm, 5 mm, 4 mm, 3 mm, 2 mm, 1 mm or less. Each increment provides advantage given the proportional incremental decrease in the amount of material used for fabricating the unitary planar reflector array.

The combination of any of the above-listed angles with any of the above listed widths is expressly provided for. Each available combination will not be individually recited for reasons of clarity and brevity.

The reflector array is preferably dimensioned so as to be easily transported and handled. In that regard, an edge of the reflector array may be less than about 4000 cm, 3000 cm, 2000 cm or 1000 cm. In terms of footprint, the reflector array may have an area of less than about 5 m², 4 m², 3 m², 2 m² or 1 m².

In one particularly preferred embodiment, the reflector array has dimensions of about 900 cm×1800 cm. When assembled into a solar collector, that provides an overall frame (module) size with an aperture of <4 m, and length <6 m in the above configuration. This configuration allows for all frame structural elements to fit into a 20 ft shipping container, and each individual panel to be easily handled by one person, fit easily into a cardboard carton.

Preferably, the volume of material which forms the unitary array is less than about 100 cm3, 110 cm3, 120 cm3, 130 cm3, 140 cm3, 150 cm3, 160 cm3, 170 cm3, 180 cm3, 190 cm3, 200 cm3, 210 cm3, 220 cm3, 230 cm3, 240 cm3, 250 cm3, 260 cm3, 270 cm3, 280 cm3, 290 cm3, 300 cm3, 310 cm3, 320 cm3, 330 cm3, 340 cm3, 350 cm3, 360 cm3, 370 cm3, 380 cm3, 390 cm3, 400 cm3, 410 cm3, 420 cm3, 430 cm3, 440 cm3, 450 cm3, 460 cm3, 470 cm3, 480 cm3, 490 cm3, 500 cm3, 510 cm3, 520 cm3, 530 cm3, 540 cm3, 550 cm3, 560 cm3, 570 cm3, 580 cm3, 590 cm3, 600 cm3, 610 cm3, 620 cm3, 630 cm3, 640 cm3, 650 cm3, 660 cm3, 670 cm3, 680 cm3, 690 cm3, 700 cm3, 710 cm3, 720 cm3, 730 cm3, 740 cm3, 750 cm3, 760 cm3, 770 cm3, 780 cm3, 790 cm3, 800 cm3, 810 cm3, 820 cm3, 830 cm3, 840 cm3, 850 cm3, 860 cm3, 870 cm3, 880 cm3, 890 cm3, 900 cm3, 910 cm3, 920 cm3, 930 cm3, 940 cm3, 950 cm3, 960 cm3, 970 cm3, 980 cm3, 990 cm3, 1000 cm3, 1010 cm3, 1020 cm3, 1030 cm3, 1040 cm3, 1050 cm3, 1060 cm3, 1070 cm3, 1080 cm3, 1090 cm3, 1100 cm3, 1110 cm3, 1120 cm3, 1130 cm3, 1140 cm3, 1150 cm3, 1160 cm3, 1170 cm3, 1180 cm3, 1190 cm3, 1200 cm3, 1210 cm3, 1220 cm3, 1230 cm3, 1240 cm3, 1250 cm3, 1260 cm3, 1270 cm3, 1280 cm3, 1290 cm3, 1300 cm3, 1310 cm3, 1320 cm3, 1330 cm3, 1340 cm3, 1350 cm3, 1360 cm3, 1370 cm3, 1380 cm3, 1390 cm3, 1400 cm3, 1410 cm3, 1420 cm3, 1430 cm3, 1440 cm3, 1450 cm3, 1460 cm3, 1470 cm3, 1480 cm3, 1490 cm3, 1500 cm3, 1510 cm3, 1520 cm3, 1530 cm3, 1540 cm3, 1550 cm3, 1560 cm3, 1570 cm3, 1580 cm3, 1590 cm3, 1600 cm3, 1610 cm3, 1620 cm3, 1630 cm3, 1640 cm3, 1650 cm3, 1660 cm3, 1670 cm3, 1680 cm3, 1690 cm3, 1700 cm3, 1710 cm3, 1720 cm3, 1730 cm3, 1740 cm3, 1750 cm3, 1760 cm3, 1770 cm3, 1780 cm3, 1790 cm3, 1800 cm3, 1810 cm3, 1820 cm3, 1830 cm3, 1840 cm3, 1850 cm3, 1860 cm3, 1870 cm3, 1880 cm3, 1890 cm3, 1900 cm3, 1910 cm3, 1920 cm3, 1930 cm3, 1940 cm3, 1950 cm3, 1960 cm3, 1970 cm3, 1980 cm3, 1990 cm3, 2000 cm3, 2010 cm3, 2020 cm3, 2030 cm3, 2040 cm3, 2050 cm3, 2060 cm3, 2070 cm3, 2080 cm3, 2090 cm3, 2100 cm3, 2110 cm3, 2120 cm3, 2130 cm3, 2140 cm3, 2150 cm3, 2160 cm3, 2170 cm3, 2180 cm3, 2190 cm3, 2200 cm3, 2210 cm3, 2220 cm3, 2230 cm3, 2240 cm3, 2250 cm3, 2260 cm3, 2270 cm3, 2280 cm3, 2290 cm3, 2300 cm3, 2310 cm3, 2320 cm3, 2330 cm3, 2340 cm3, 2350 cm3, 2360 cm3, 2370 cm3, 2380 cm3, 2390 cm3, 2400 cm3, 2410 cm3, 2420 cm3, 2430 cm3, 2440 cm3, 2450 cm3, 2460 cm3, 2470 cm3, 2480 cm3, 2490 cm3, 2500 cm3, 2510 cm3, 2520 cm3, 2530 cm3, 2540 cm3, 2550 cm3, 2560 cm3, 2570 cm3, 2580 cm3, 2590 cm3, 2600 cm3, 2610 cm3, 2620 cm3, 2630 cm3, 2640 cm3, 2650 cm3, 2660 cm3, 2670 cm3, 2680 cm3, 2690 cm3, 2700 cm3, 2710 cm3, 2720 cm3, 2730 cm3, 2740 cm3, 2750 cm3, 2760 cm3, 2770 cm3, 2780 cm3, 2790 cm3, 2800 cm3, 2810 cm3, 2820 cm3, 2830 cm3, 2840 cm3, 2850 cm3, 2860 cm3, 2870 cm3, 2880 cm3, 2890 cm3, 2900 cm3, 2910 cm3, 2920 cm3, 2930 cm3, 2940 cm3, 2950 cm3, 2960 cm3, 2970 cm3, 2980 cm3, 2990 cm3, 3000 cm3, 3010 cm3, 3020 cm3, 3030 cm3, 3040 cm3, 3050 cm3, 3060 cm3, 3070 cm3, 3080 cm3, 3090 cm3, 3100 cm3, 3110 cm3, 3120 cm3, 3130 cm3, 3140 cm3, 3150 cm3, 3160 cm3, 3170 cm3, 3180 cm3, 3190 cm3, 3200 cm3, 3210 cm3, 3220 cm3, 3230 cm3, 3240 cm3, 3250 cm3, 3260 cm3, 3270 cm3, 3280 cm3, 3290 cm3, 3300 cm3, 3310 cm3, 3320 cm3, 3330 cm3, 3340 cm3, 3350 cm3, 3360 cm3, 3370 cm3, 3380 cm3, 3390 cm3, 3400 cm3, 3410 cm3, 3420 cm3, 3430 cm3, 3440 cm3, 3450 cm3, 3460 cm3, 3470 cm3, 3480 cm3, 3490 cm3, 3500 cm3, 3510 cm3, 3520 cm3, 3530 cm3, 3540 cm3, 3550 cm3, 3560 cm3, 3570 cm3, 3580 cm3, 3590 cm3, 3600 cm3, 3610 cm3, 3620 cm3, 3630 cm3, 3640 cm3, 3650 cm3, 3660 cm3, 3670 cm3, 3680 cm3, 3690 cm3, 3700 cm3, 3710 cm3, 3720 cm3, 3730 cm3, 3740 cm3, 3750 cm3, 3760 cm3, 3770 cm3, 3780 cm3, 3790 cm3, 3800 cm3, 3810 cm3, 3820 cm3, 3830 cm3, 3840 cm3, 3850 cm3, 3860 cm3, 3870 cm3, 3880 cm3, 3890 cm3, 3900 cm3, 3910 cm3, 3920 cm3, 3930 cm3, 3940 cm3, 3950 cm3, 3960 cm3, 3970 cm3, 3980 cm3, 3990 cm3, 4000 cm3, 4010 cm3, 4020 cm3, 4030 cm3, 4040 cm3, 4050 cm3, 4060 cm3, 4070 cm3, 4080 cm3, 4090 cm3, 4100 cm3, 4110 cm3, 4120 cm3, 4130 cm3, 4140 cm3, 4150 cm3, 4160 cm3, 4170 cm3, 4180 cm3, 4190 cm3, 4200 cm3, 4210 cm3, 4220 cm3, 4230 cm3, 4240 cm3, 4250 cm3, 4260 cm3, 4270 cm3, 4280 cm3, 4290 cm3, 4300 cm3, 4310 cm3, 4320 cm3, 4330 cm3, 4340 cm3, 4350 cm3, 4360 cm3, 4370 cm3, 4380 cm3, 4390 cm3, 4400 cm3, 4410 cm3, 4420 cm3, 4430 cm3, 4440 cm3, 4450 cm3, 4460 cm3, 4470 cm3, 4480 cm3, 4490 cm3, 4500 cm3, 4510 cm3, 4520 cm3, 4530 cm3, 4540 cm3, 4550 cm3, 4560 cm3, 4570 cm3, 4580 cm3, 4590 cm3, 4600 cm3, 4610 cm3, 4620 cm3, 4630 cm3, 4640 cm3, 4650 cm3, 4660 cm3, 4670 cm3, 4680 cm3, 4690 cm3, 4700 cm3, 4710 cm3, 4720 cm3, 4730 cm3, 4740 cm3, 4750 cm3, 4760 cm3, 4770 cm3, 4780 cm3, 4790 cm3, 4800 cm3, 4810 cm3, 4820 cm3, 4830 cm3, 4840 cm3, 4850 cm3, 4860 cm3, 4870 cm3, 4880 cm3, 4890 cm3, 4900 cm3, 4910 cm3, 4920 cm3, 4930 cm3, 4940 cm3, 4950 cm3, 4960 cm3, 4970 cm3, 4980 cm3, 4990 cm3, or 5000 cm3. Each increment provides advantage given the proportional incremental decrease in the amount of material used for fabricating the unitary planar reflector array.

In one embodiment of the first aspect, the array as a whole, or at least the substrate surfaces upon which the reflective coating is disposed is an artificial (preferably UV stable) polymeric material. Low cost UV stable plastics which are generally resistant to impact are preferred given the low cost and ease of moulding.

In one embodiment of the first aspect, the artificial polymeric material is a substantially rigid UV stable plastic such as ABS, CAB, ECTFE, ETFE, EVA, FEP, HDPE, HIP, LDPE, PAI, PCTFE and PETG, PFA, polycarbonate, PPSU, PVDF, UHMW, and functional equivalents thereof.

Of course, non-polymeric materials such as metals and ceramics may be used in fabrication of the reflector array, however for reasons of economy, weight, or ease of fabrication plastics are generally preferred.

In one embodiment of the first aspect, the unitary planar solar radiation reflector array is formed as, or from, a single piece of artificial UV stable polymeric material. In one embodiment of the first aspect, the substrate of the unitary planar solar radiation reflector array is formed by moulding (including injection moulding and rotational moulding), casting, extruding, slumping, 3-D printing, or stamping.

Applicant proposes that methods for manufacturing optical computer media (such as Compact Disc™) may also be applicable to the fabrication of the present reflector arrays. The manufacture of optical media is in a disparate technological field, yet the present inventor has realised the applicability of such manufacturing methods to the present invention. Optical media is fabricated from optical grade polycarbonate which provides virtually total luminous transmittance, and very low haze factor. This amorphous thermoplastic is highly transparent to visible light, rating highest among transparent, rigid thermoplastics, and possesses superior light transmission characteristics to many kinds of glass. Polycarbonate has 250 times the impact strength of float glass and 30 times that of acrylic.

Using optical media manufacturing technology, it may be practicable to manufacture a pressed CST (Concentrated Solar Thermal) panel from UV stable optical grade polycarbonate having the required angled upwardly facing surfaces, and to metalize the surfaces with the same or similar sputtering technique as used in optical media and then apply a protective lacquer. The result is a reflector array several mm thick, with extremely high resistance to impact. Solar radiation will pass through the optically clear polycarbonate, and be reflected toward the absorber by the reflective surface (as for a Compact Disc™). As will be appreciated, the reflective surface is on the underside of the polycarbonate substrate, that being the reverse of existing solar reflectors where the reflective surface is applied to a translucent substrate.

An alternative approach to construction may involve a thin optical grade UV stable polycarbonate reflective surface bonded to an HDPE (or similar low cost filler material) and a backing sheet of zincalume, UV stable EVA, DuPont™ Tedlar® PVF film or equivalent backsheet. Such arrangements are found in existing photovoltaic cells, whereby the strength of the panel is afforded mainly from glass or optical polycarbonate, or may be considered as analogous to the manufacture of Aluminium Composite Panels (ACP) and similar high volume sheet material.

Subtractive methods may also be useful in forming the substrate. For example, selective laser-induced etching (SLE) allows for high precision etching of transparent materials such as fused silica. SLE (or other etching technology) may also be used to create a mould for the production of the substrate.

In one embodiment of the first aspect, the upwardly facing reflective surfaces of the reflector array are either planar reflectors or curvilinear reflectors. The upwardly facing reflective surfaces may be configured, when taken together, to provide a virtual curved, parabolic, or near parabolic surface capable of directing and/or concentrating solar radiation on an absorber disposed there over.

In one embodiment, each of the upwardly facing reflective surfaces is a parabolic confocal facet.

In one embodiment of the first aspect, the unitary planar solar radiation reflector array comprises a protective layer disposed over the reflector array, the protective layer allowing transmission of incident solar radiation to the reflective surface.

In one embodiment, where the reflective coating material is applied to the underside of a transparent substrate material, then the transparent substrate material performs the further function of protecting the upwardly facing reflective surface.

Where the reflective coating material is applied onto an upwardly facing surface of the substrate (and is therefore otherwise exposed to the elements) a protective layer may be applied by spray onto the coating of the upright surfaces, or by laying a transparent plastic sheet or pane of glass over the reflective coating. The protective layer is intended to protect the coating so as to prevent degradation of its reflective properties over time. Thus, the protective layer may form a barrier to dirt, water and other environmental contaminants that may corrode or simply soil the coating. Oxidation may lead to roughening of the coating layer, cracking and detachment any of which will interfere with the ability of the coating to efficiently reflect incident radiation to an absorber.

The use of glass or transparent plastic sheeting is preferred as a flat surface is presented across the entire reflector array, this allowing for easy and automated cleaning. Where multiple reflector arrays are abutted to form a super reflector array, a single piece of glass or plastic sheeting may overly all reflector arrays, again to facilitate cleaning.

In one embodiment of the first aspect, a space is present between the protective layer and the reflector array. In one embodiment of the first aspect, the space is a substantially sealed space, and the space comprises a gas or a gaseous mixture that is different to the surrounding environment. An inert or generally unreactive gas (such as nitrogen) may occupy the space, thereby inhibiting oxidation of the coating.

In a second aspect, there is provided by the present invention a solar energy collector comprising the unitary planar solar radiation reflector array of any embodiment of the first aspect, and a common focal absorber located over the upwardly facing reflective surfaces of the unitary planar solar radiation reflector array and upon which incident solar radiation from the reflectors of the unitary planar reflector is reflected, the absorber configured to receive a heat absorbing medium adapted to absorb heat from the reflected radiation.

An advantage of some embodiments of the present reflector arrays is that greater manufacturing accuracy is possible, resulting in less diffusion and loss of reflected sunlight, higher system efficiency and potentially higher concentration ratios. The ability to configure very narrow reflective surfaces allows for the establishment of a narrow focal line. Thus, incident solar radiation may be focussed onto a narrow focal line, which results in a greater concentrating effect being achieved. By contrast prior art reflectors based on discrete mirrors or a single parabolic mirror are unable to achieve the same accuracy and narrowness of the focal line, and therefore are unable to achieve comparable levels of concentration.

A more narrow focal line may allow for a solar collector comprising the present reflector to utilize a smaller diameter and lower cost absorber tube.

Especially for embodiments which provide for a relatively short focal length (as discussed infra), the narrower focal line will simply be more accurate, with less diffusion, and therefore a lower likelihood of reflected solar radiation missing the absorber.

Furthermore, the present reflector arrays may in some embodiments allow for shorter focal lengths. In particular, reflective surfaces may be provided that are highly angled so as to allow the absorber to be disposed closer to the reflector array upper surface. Again, this allows for reflected radiation to be more accurately trained on an absorber.

A prior art collector with an azimuth of 3600 mm focusing onto a 70 mm diameter absorber tube may provide a concentration of just over 50 suns. With substantially increased concentrations provided by the present invention, it may even be possible to achieve at least 300 suns in a single axis tracker with a single aperture of 600 mm and a focal length of 300 mm (compared with a focal length of 1860 mm for a prior art collector).

The ability to achieve higher concentrations may allow for substantially higher temperatures to be reached, which would in turn facilitate the use of higher efficiency steam Rankine Cycle or even Brayton Cycle turbines.

The higher concentrations achievable by the present reflector arrays may be used to also facilitate Concentrated Photovoltaic (CPV), which is currently only useful in the context of a dual axis tracker.

It is further contemplated that the present reflector arrays may be configured to provide multiple focus lines and be coupled to multiple absorbers.

In one embodiment of the second aspect, the solar energy collector comprises an elevated support structure for the unitary array of reflectors and the absorber.

In one embodiment of the second aspect, the solar energy collector comprises upright elevation means to which the support structure is pivotally mounted to allow controlled rotation of the reflector array and absorber simultaneously about a pivotal axis so as to track the movement of the sun.

For embodiments of the reflector array that are susceptible to wind damage, the elevation means may be configured to lower the reflector array (optionally to ground level) so as avoid damage. Low cost detectors are available, which may be linked to a drive which lowers the reflector array upon triggering by the detector. Once wind speed has decreased, the drive elevates the reflector array to its working position.

In one embodiment of the second aspect, the absorber further comprises a secondary reflector located over the absorber and configured to reflect to the absorber any reflected radiation from the reflector array which does not strike the absorber.

In a third aspect, there is provided by the present invention a method for collecting solar energy, the method comprising the steps of providing the solar energy collector of any embodiment of the first aspect, disposing a heat absorbing medium into the absorber, causing or allowing solar radiation to incide on the reflector array such that the heat absorbing medium is heated by the reflected solar radiation.

It will be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Thus, while there has been described what are believed to be the preferred embodiments of the invention, those skilled in the art will recognize that other and further modifications may be made thereto without departing from the spirit of the invention, and it is intended to claim all such changes and modifications as fall within the scope of the invention. Functionality may be added or deleted from diagrams and operations may be interchanged among functional blocks. Steps may be added or deleted to methods described within the scope of the present invention.

The present invention will now be more fully described by reference to the following non-limiting embodiments.

### DETAILED DESCRIPTION OF PREFERRED EMBODIMENTS

With respect to the drawings:

FIG. 1 is a prior art installation of a parabolic trough reflector showing the scale and complexity of the support structures.

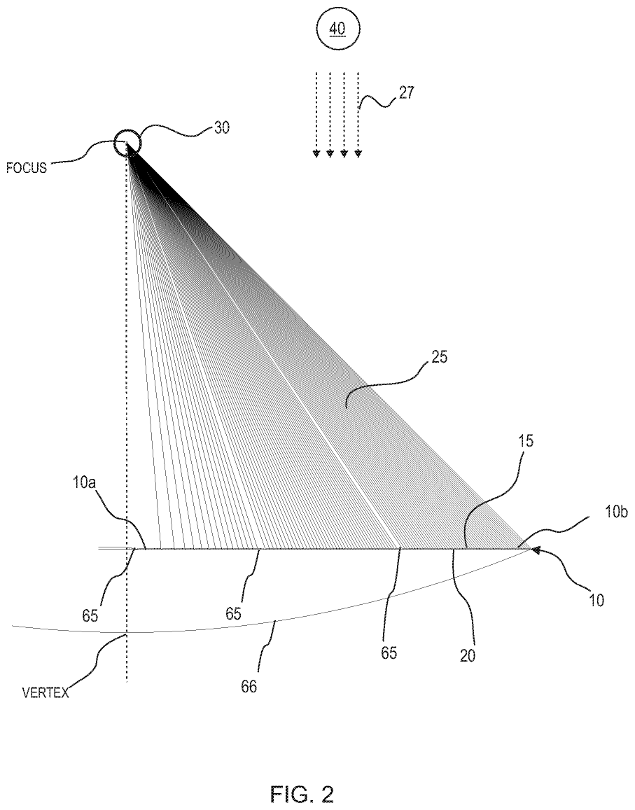

FIG. 2 is a cross-sectional diagrammatic representation of a reflector array and absorber of an exemplary solar energy collector of the present invention.

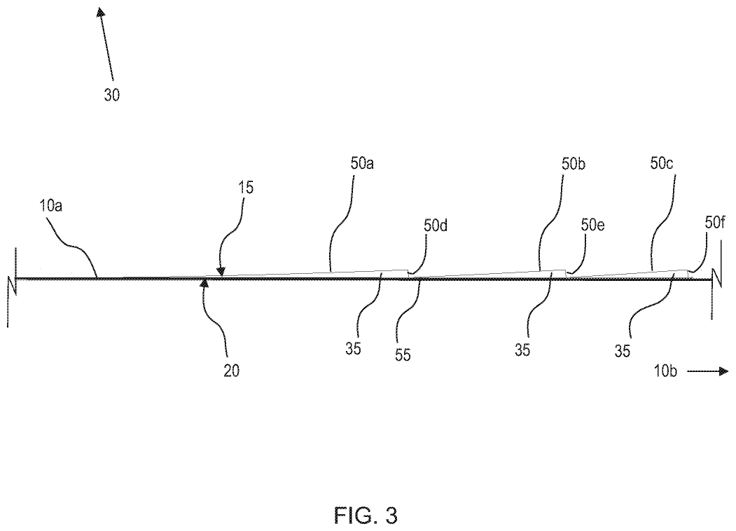

FIG. 3 is a magnification of a section of the cross-sectional diagrammatic representation of the reflector array shown in FIG. 2.

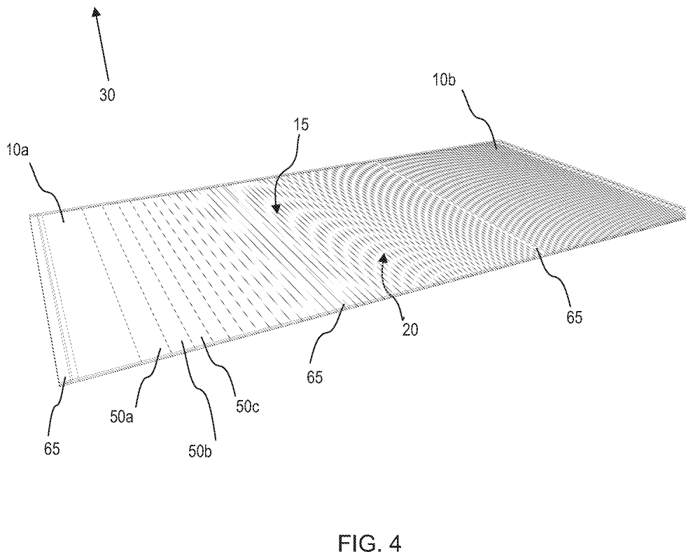

FIG. 4 is a perspective diagrammatic representation of the reflector array shown in FIG. 2.

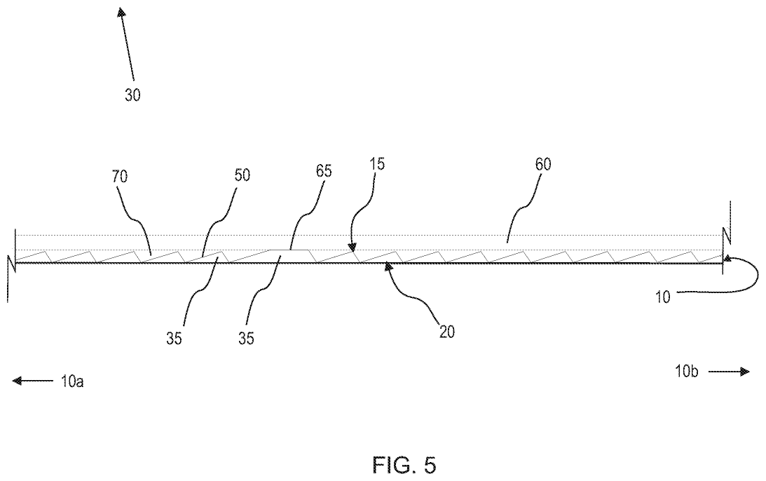

FIG. 5 is a cross-sectional diagrammatic representation of the reflector array of FIG. 2, as fitted with a toughened glass layer.

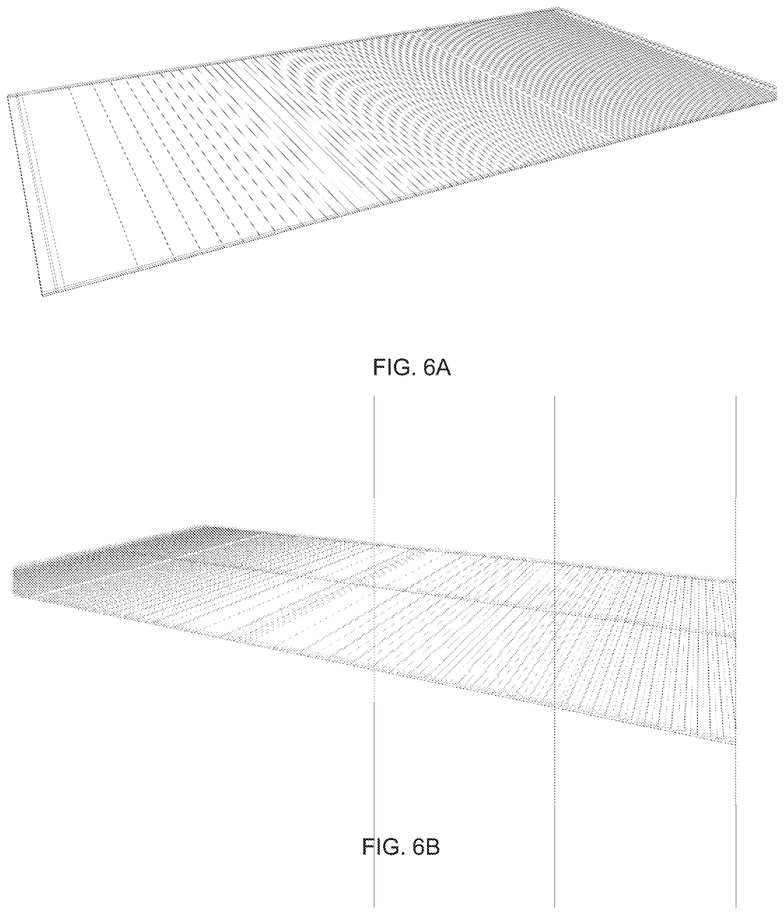

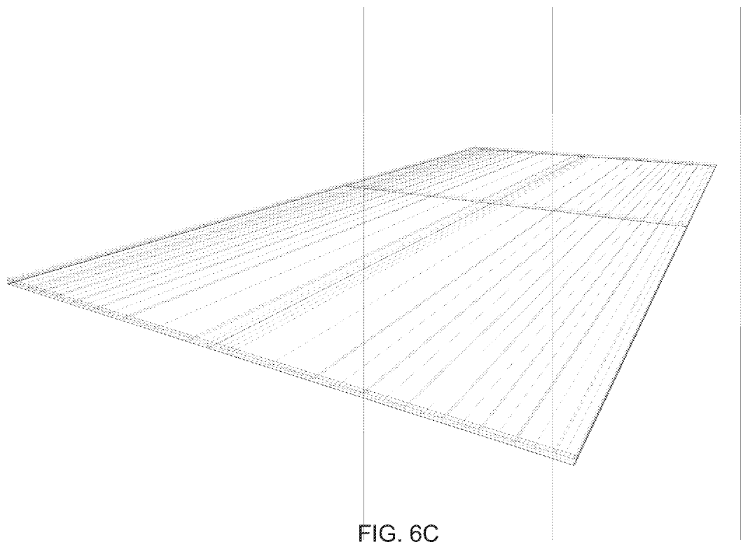

FIGS. 6A, 6B and 6C are perspective diagrammatic representation of several reflector arrays, each of dimension 1800 mm×900 mm although each configured for different applications.

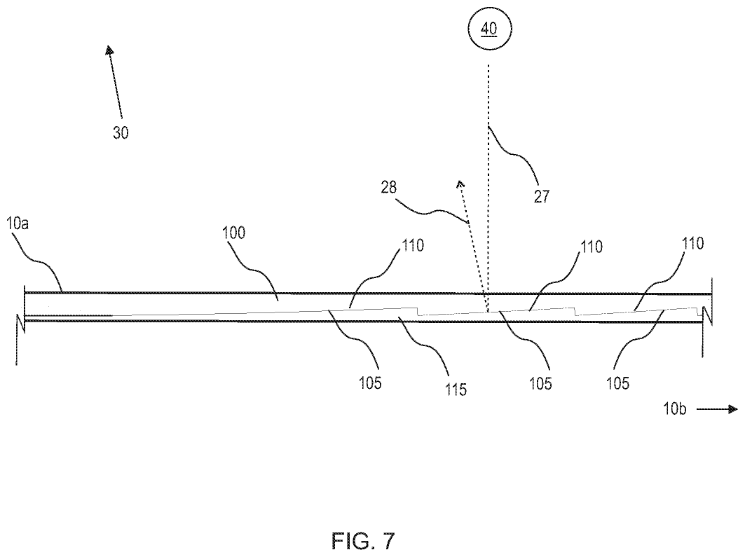

FIG. 7 is a cross-sectional diagrammatic representation of a reflector array whereby a metallized reflective coating is applied to the underside of an optically transparent substrate.

Reference is made firstly to FIG. 2 which shows a portion of a solar energy collector of the present invention comprising a unitary planar reflector array 10, having an upper side 15 and a lower side 20. The upper side has a plurality of upwardly facing reflective surfaces (not readily visible in this drawing, but clearly shown in following drawings).

The closely spaced lines 25 represent beams of solar radiation reflected from the reflector array 10. The beams 27 of incoming solar radiation from the sun 40 are essentially parallel to each other and at 90 degrees to the plane of the reflector array 10. It will be noted that the reflected beams 25 are directed toward an absorber pipe 30 maintained by a support (not shown) over the reflector array 10. A heat transfer medium runs through the pipe absorber 30, and is heated by the radiation beams 25 impinging on the outside of the pipe absorber 30.

The upwardly facing reflective surfaces of the upper side 15 of the reflector array 10 are curvilinear in this embodiment, and angled to the plane of reflector array 10. Each of the upwardly facing reflective surfaces (which are shown in greater detail in FIG. 3) is a confocal parabolic facet, the focal length of each facet incrementally increasing with increasing distance from the absorber. The aggregate of all facets providing one half of a parabolic curve, wherein the absorber coincides with the common focus of all of the parabolic curve elements.

Curve 66 represents one of the plurality of curves which derive the virtual parabolic curve resulting from the aggregate of all reflective surfaces. The remaining curves which so define the remainder of the reflective surfaces are not shown for clarity.

In reality, a second reflector array (being a mirror image) would be disposed to the left (as drawn) of the absorber 30, with the second reflector array providing the second half of the precise parabolic curve.

The angles of the reflective upwardly facing reflective surfaces are shallow toward the end 10a of the reflector array 10, increasing incrementally toward the end 10b of the reflector array 10 as discussed further infra.

Turning now to FIG. 3, greater detail of the reflector array is shown. Three upwardly facing reflective surfaces 50a, 50b, 50c are shown, being the first three surfaces (from to left to right) starting from the point marked 10a of FIG. 2.

Although not obvious from the drawing, the upwardly facing reflective surfaces are at different angles: 50a<50b<50c. The actual angles are chosen such that solar radiation incident on the surface is directed to the absorber pipe 30 disposed in a fixed position over the reflector array 10. The angles are the product of the increasing slope of the virtual parabolic curve (resulting from the aggregate of all reflective surfaces) as it moves away from the axis of symmetry, according to the well known formula y=ax².

The upwardly facing reflective surfaces 50a, 50b, 50c are formed by a PVD process. In the PVD process the underlying substrate 35 is coated with a thin reflective aluminium film. For ease of manufacture, all surfaces 50a, 50b, 50c, 50d, 50e, 50f are coated with the aluminium film, however it is preferred that surfaces 50d, 50e and 50f are of reduced reflectance and/or reduced specular reflection. Reduction in the reflectance or specularity of the surfaces 50d, 50e and 50f may be achieved by roughening or removing the aluminium film (for example by laser ablation). Alternatively, the underlying substrate 35 may have dimpling in the areas 50d, 50e and 50f such that when the aluminium film is applied, light is scattered in an incoherent manner. Such dimpling or surface roughening may be most easily achieved during stamping or rollforming—this area of the mould is roughed and the reflective surface is polished.

It will be noted that solar radiation reflected from surfaces 50d, 50e and 50f would scatter and diffuse, and not be directed to the focus line. The reflectivity of these surface should therefore be eliminated or reduced to avoid reflection of sunlight to other than the absorber tube.

The substrate 35 may be formed by industrial 3-D printing (using LDPE) onto a 0.5 mm zincalume sheet 55. For high volume production, an accurate extrusion, stamping or similar thermoforming method will more likely be used to form the substrate. The extruded substrate may be sandwiched between a zincalume sheet, and protective glass sheet (as discussed more fully infra)

Turning now to FIG. 5, there is shown an embodiment of the invention having a protective toughened glass sheet 60 applied over the upper side 15 of the reflector array 10. The toughened glass 60 rests on support surfaces 65, of which there may be two or more for a given reflector array. The position of the support surfaces 65 in the context of a reflector array may be seen by reference to FIG. 2 and FIG. 4.

In this embodiment, the toughened glass 60 forms a seal such that the chambers (one marked as 70) may retain a non-reactive gas therein.

FIGS. 6A, 6B and 6C show the modular nature of certain embodiments of the present reflector array. FIG. 6A shows a 1800 mm×900 mm half-reflector panel, two or which can be opposed (in a mirror image manner) to form a full reflector panel of dimension 3600 mm×900 mm, with the absorber tube (not shown) running parallel to the short axis of symmetry of the full panel. FIG. 6B shows a full reflector panel of dimension 1800 mm×900 mm, with the absorber tube (not shown) running parallel to the short axis of symmetry of the full panel. FIG. 6C shows a full reflector panel of dimension 1800 mm×900 mm, with the absorber tube (not shown) running parallel to the long axis of symmetry of the full panel.

FIG. 7 shows a reflector array formed from a transparent substrate 100 moulded from an optically transparent UV stable polycarbonate of the type used in CompactDisc™ manufacture. The transparent substrate 100 is moulded so as to have a plurality of downwardly facing surfaces 105. A thin metallized film (not shown) is applied to the downwardly facing surface 105 in a manner similar to CompactDisc™ manufacture, so as to as to provide upwardly facing reflective surfaces 110. The underside of the metallized coating is protected by the addition of a liquid protective coating 115, which is subsequently hardened in a manner similar to that for CompactDisc™ manufacture. In use, incident solar radiation 27 is reflected 28 off the metallized coating toward the absorber 30.

It will be understood that the invention is not limited to any particular embodiment of the invention as disclosed herein. Equivalents, extensions, variations, deviations, etc., of the various exemplified embodiments will be apparent to persons skilled in the relevant art(s) based on the teachings contained herein. Such equivalents, extensions, variations, deviations, etc., are within the scope and spirit of the present invention.

It will be further appreciated that any of the features of any aspect of the invention disclosed herein are all combinable with each other in any number and in any combination without any limitation whatsoever. The ability to combine any features in any number to provide a range of combinations extends to features defined in the following claims.

1. A unitary planar solar radiation reflector array having a plurality of upwardly facing reflective surfaces each of which is configured to reflect incident solar radiation, wherein each upwardly facing reflective surface comprises a substrate coated with a coating material.

2. The unitary planar solar radiation reflector array of claim 1, wherein the coating material comprises a metal or a compound comprising a metal.

3. The unitary planar solar radiation reflector array of claim 2, wherein the coating formed by the coating material has a substantially even thickness.

4. The unitary planar solar radiation reflector array of claim 1, wherein the coating formed by the coating material is a film.

5. The unitary planar solar radiation reflector array of claim 1, wherein the coating formed by the coating material has a thickness of less than about 100 μm.

6. The unitary planar solar radiation reflector array of claim 1, wherein the coating is formed by a metal deposition method.

7. The unitary planar solar radiation reflector array of claim 1, wherein the coating is formed by a vapour deposition method or a thermal spray method.

8. The unitary planar solar radiation reflector array of claim 1 having an axis and/or a plane, wherein the upwardly facing reflective surfaces of the reflector array are each disposed at an angle to the axis and/or plane.

9. The unitary planar solar radiation reflector array of claim 8, wherein the angle of each upwardly facing reflective surface is fixed.

10. The unitary planar solar radiation reflector array of claim 9, wherein the upwardly facing reflective surfaces of the reflector array are disposed at different angles, the angle increasing toward an edge of the reflector array.

11. The unitary planar solar radiation reflector array of claim 1, wherein the array is formed as a panel.

12. The unitary planar solar radiation reflector array of claim 11, wherein the substrate is an artificial polymeric material.

13. The unitary planar solar radiation reflector array of claim 1, wherein the substrate is formed by moulding, casting, extruding, slumping, 3-D printing, or stamping.

14. The unitary planar solar radiation reflector array of claim 1, wherein each of the upwardly facing reflective surfaces of the reflector array are elongate and extend in parallel rows.

15. The unitary planar solar radiation reflector array of claim 1, wherein each of the upwardly facing reflective surfaces of the reflector array are either planar or curvilinear, or a confocal parabolic facet, focal length of each confocal parabolic facet incrementally increasing with increasing distance from an absorber such that an aggregate of all the confocal parabolic facets provides a segment of a parabolic curve.

16. The unitary planar solar radiation reflector array of claim 1, comprising a protective layer disposed over the reflector array, the protective layer allowing transmission of incident solar radiation to the reflective surface.

17. A solar energy collector comprising:
a unitary planar solar radiation reflector array having a plurality of upwardly facing reflective surfaces each of which is configured to reflect incident solar radiation, wherein each upwardly facing reflective surface is formed by coating a substrate with a coating material, and
a common focal absorber located over the upwardly facing reflective surfaces of the unitary solar radiation reflector array and upon which incident solar radiation from the reflectors of the unitary planar reflector is reflected, the absorber configured to receive a heat absorbing medium adapted to absorb heat from the reflected radiation.

18. The solar energy collector of claim 17, comprising an elevated support structure for the unitary array of reflectors and the absorber.

19. A method for collecting solar energy, the method comprising:
providing a solar energy collector comprising:
a unitary planar solar radiation reflector array having a plurality of upwardly facing reflective surfaces each of which is configured to reflect incident solar radiation, wherein each upwardly facing reflective surface is formed by coating a substrate with a coating material, and
a common focal absorber located over the upwardly facing reflective surfaces of the unitary solar radiation reflector array and upon which incident solar radiation from the reflectors of the unitary planar reflector is reflected, the absorber configured to receive a heat absorbing medium adapted to absorb heat from the reflected radiation,
disposing a heat absorbing medium into the absorber, and
causing or allowing solar radiation to incide on the reflector array such that the heat absorbing medium is heated by the reflected solar radiation.
